(19) United States
(12) Patent Application Publication
(10) Pub. No.: US 2024/0219428 A1
(43) Pub. Date: Jul. 4, 2024

(54) CURRENT SENSOR, METHOD OF CORRECTING THE SAME, AND METHOD OF CORRECTING A PLURALITY OF CURRENT SENSORS

(71) Applicant: Murata Manufacturing Co., Ltd., Nagaokakyo-shi (JP)

(72) Inventors: Junya KOMODA, Nagaokakyo-shi (JP); Tatsuki MAEDA, Nagaokakyo-shi (JP)

(21) Appl. No.: 18/607,619

(22) Filed: Mar. 18, 2024

Related U.S. Application Data
(63) Continuation of application No. PCT/JP2022/031865, filed on Aug. 24, 2022.

(30) Foreign Application Priority Data
Sep. 29, 2021 (JP) 2021-159429

(51) Int. Cl. G01R 15/20; G01R 19/00

(52) U.S. Cl. CPC G01R 15/202; G01R 15/205; G01R 19/0092

(57) ABSTRACT

A current sensor includes first and second magnetic detectors. An interval in a second direction between the second magnetic detector and a measurement target bus bar is larger than an interval in the second direction between the first magnetic detector and the measurement target bus bar. While a processing circuit performs mutual reduction and cancellation of detection values obtained by the first and second magnetic detectors, of a magnetic field component in a first direction of an external magnetic field generated from an adjacent bus bar, the processing circuit calculates a value of a current that flows through the measurement target bus bar based on a difference in absolute value between the detection values obtained by the first and second magnetic detectors, of the magnetic field component in the first direction of the magnetic field generated by the current that flows in the measurement target bus bar.

### CROSS REFERENCE TO RELATED APPLICATIONS

This application claims the benefit of priority to Japanese Patent Application No. 2021-159429 filed on Sep. 29, 2021 and is a Continuation Application of PCT Application No. PCT/JP2022/031865 filed on Aug. 24, 2022. The entire contents of each application are hereby incorporated herein by reference.

### BACKGROUND OF THE INVENTION

### 1. Field of the Invention

The present invention relates to current sensors, methods of correcting the same, and methods of correcting current sensors.

### 2. Description of the Related Art

Japanese Patent Laid-Open No. 2005-195427 discloses a configuration of a current measurement apparatus. The current measurement apparatus disclosed in Japanese Patent Laid-Open No. 2005-195427 includes a plurality of magnetic sensors and signal processing means. The signal processing means calculates a value of a current that flows in a measurement target conductor, based on an output signal on which a difference in sensitivity to a current, of the magnetic sensors is reflected.

In the current measurement apparatus described in Japanese Patent Laid-Open No. 2005-195427, an external magnetic field can be canceled only when a uniform external magnetic field is applied to the plurality of magnetic sensors.

### SUMMARY OF THE INVENTION

Example embodiments of the present invention provide current sensors, methods of correcting the same, and methods of correcting a plurality of current sensors that each enable accurate measurement of a value of a current to be measured, by canceling an external magnetic field even when a non-uniform external magnetic field is applied to a plurality of magnetic detectors.

A current sensor according to an example embodiment on the present invention includes a measurement target bus bar, an adjacent bus bar, a first magnetic detector and a second magnetic detector, a processing circuit, and a signal terminal. A current to be measured flows through the measurement target bus bar. The adjacent bus bar is adjacent to the measurement target bus bar at a distance in a first direction. Each of the first magnetic detector and the second magnetic detector detects a magnetic field component in the first direction of a magnetic field generated by the current that flows through the measurement target bus bar while the first magnetic detector and the second magnetic detector are opposed to the measurement target bus bar at a distance in a second direction orthogonal or substantially orthogonal to the first direction. The processing circuit is electrically connected to each of the first magnetic detector and the second magnetic detector and is configured or programmed to process a detection signal from each of the first magnetic detector and the second magnetic detector. The signal terminal is electrically connected to the processing circuit and outputs an output signal resulting from processing of the detection signal by the processing circuit. An interval in the second direction between the second magnetic detector and the measurement target bus bar is larger than an interval in the second direction between the first magnetic detector and the measurement target bus bar. While the processing circuit performs mutual reduction and cancellation of detection values obtained by the first magnetic detector and the second magnetic detector, of the magnetic field component in the first direction of an external magnetic field generated from the adjacent bus bar, the processing circuit is configured or programmed to calculate a value of the current that flows through the measurement target bus bar based on a difference in absolute value between the detection values obtained by the first magnetic detector and the second magnetic detector, of the magnetic field component in the first direction of the magnetic field generated by the current that flows in the measurement target bus bar.

According to example embodiments of the present invention, even when a non-uniform external magnetic field is applied to a plurality of magnetic detectors, an external magnetic field is able to be canceled and a value of a current to be measured can accurately be measured.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view showing a configuration of a plurality of current sensors according to a first example embodiment of the present invention.

FIG. 2 is a side view of the plurality of current sensors in FIG. 1 from a direction shown with an arrow II.

FIG. 3 is a cross-sectional view of a current sensor in FIG. 2 from a direction shown with an arrow III.

FIG. 4 is a perspective view of the current sensor in FIG. 2 from a direction shown with an arrow IV.

FIG. 5 is a plan view of the current sensor in FIG. 4 from a direction shown with an arrow V.

FIG. 6 is a schematic diagram showing a magnetic field applied to each of a first magnetic detector and a second magnetic detector when currents flow through a plurality of measurement target bus bars in the plurality of current sensors according to the first example embodiment of the present invention.

FIG. 7 is a circuit diagram showing a circuit configuration of the first magnetic detector and the second magnetic detector and a processing circuit in the plurality of current sensors according to the first example embodiment of the present invention.

FIG. 8 shows a graph of a relationship between a value of a current that flows through each of a first bus bar and a third bus bar and detected magnetic field intensity detected by each of the first magnetic detector and the second magnetic detector of a second current sensor when the current flows only through the first bus bar and the third bus bar.

FIG. 9 shows a graph of a relationship between a value of a current that flows through a second bus bar and detected magnetic field intensity detected by each of the first magnetic detector and the second magnetic detector of the second current sensor when the current flows only through the second bus bar.

FIG. 10 shows a graph of a relationship between a value of a current that flows through each of the first bus bar to the third bus bar and detected magnetic field intensity detected by each of the first magnetic detector and the second magnetic detector of the second current sensor when the current flows through each of the first bus bar to the third bus bar.

FIG. 11 shows a graph of a relationship between a value of a current that flows through each of the first bus bar to the third bus bar and an output value from each of the first magnetic detector and the second magnetic detector of the second current sensor when the current flows through each of the first bus bar to the third bus bar.

FIG. 12 shows a graph of a differential output value between an output value based on a magnetic field component B1 from the first magnetic detector before correction and an output value based on a magnetic field component B2 from the second magnetic detector and a differential output value between an output value based on a magnetic field component Bn1 from the first magnetic detector before correction and an output value based on a magnetic field component Bn2 from the second magnetic detector.

FIG. 13 shows a graph of a differential output value between an output value based on magnetic field component B1 from the first magnetic detector after correction and an output value based on magnetic field component B2 from the second magnetic detector and a differential output value between an output value based on magnetic field component Bn1 from the first magnetic detector after correction and an output value based on magnetic field component Bn2 from the second magnetic detector.

FIG. 14 is a flowchart showing a method of successive correction of a plurality of current sensors according to an example embodiment of the present invention.

FIG. 15 is a plan view showing a relationship of an arrangement of a measurement target bus bar, a first magnetic detector, and a second magnetic detector in a current sensor according to a second example embodiment of the present invention.

FIG. 16 is a side view of the relationship of the arrangement in FIG. 15 from a direction shown with an arrow XVI.

FIG. 17 is a plan view showing a relationship of an arrangement of a measurement target bus bar, a first magnetic detector, and a second magnetic detector in a current sensor according to a modification of the second example embodiment of the present invention.

FIG. 18 is a front view showing the relationship of the arrangement in FIG. 17 from a direction shown with an arrow XVIII.

FIG. 19 is a side view showing the relationship of the arrangement in FIG. 17 from a direction shown with an arrow XIX.

FIG. 20 is a plan view showing a relationship of an arrangement of a measurement target bus bar, a first magnetic detector, and a second magnetic detector in a current sensor according to a third example embodiment of the present invention.

FIG. 21 is a side view of the relationship of the arrangement in FIG. 20 from a direction shown with an arrow XXI.

### DETAILED DESCRIPTION OF THE EXAMPLE EMBODIMENTS

Current sensors, methods of correcting the same, and methods of correcting current sensors according to example embodiments of the present invention will be described below with reference to the drawings. In the description of the example embodiments, the same or corresponding elements in the drawings are denoted by the same reference characters allotted and description thereof will not be repeated.

### First Example Embodiment

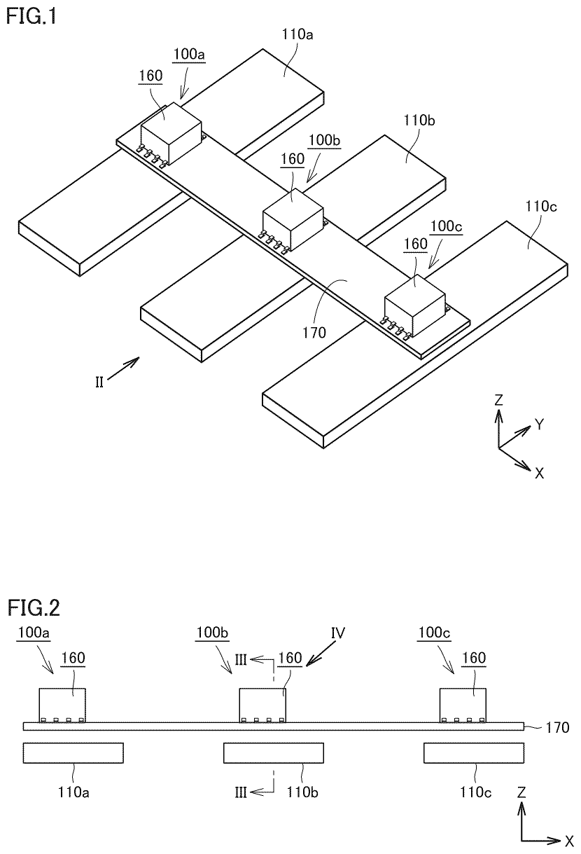

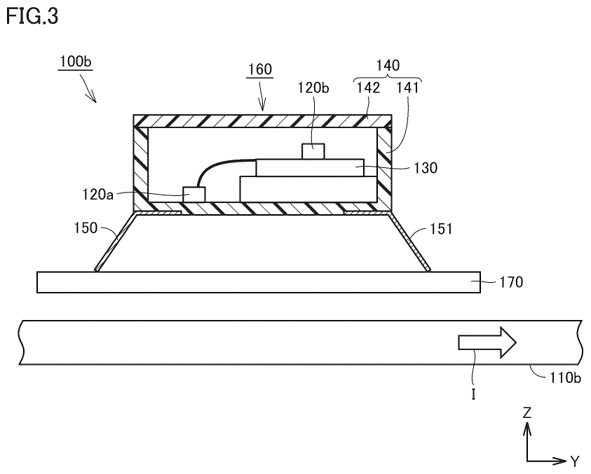

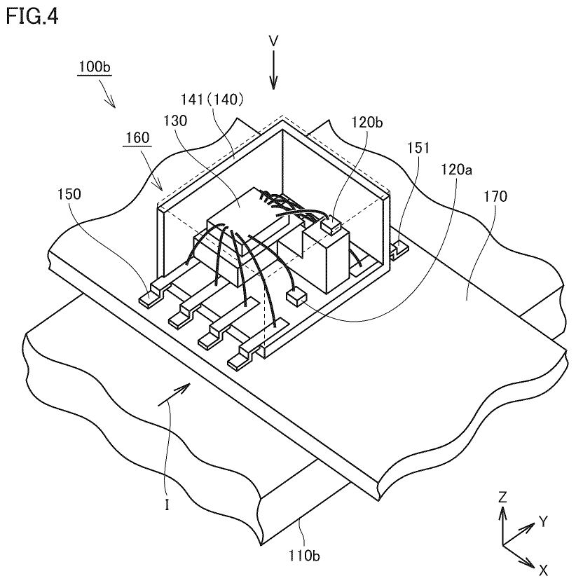

FIG. 1 is a perspective view showing a configuration of a plurality of current sensors according to a first example embodiment of the present invention. FIG. 2 is a side view of the plurality of current sensors in FIG. 1 from a direction shown with an arrow II. FIG. 3 is a cross-sectional view of a current sensor in FIG. 2 from a direction shown with an arrow III. FIG. 4 is a perspective view of the current sensor in FIG. 2 from a direction shown with an arrow IV. FIG. 5 is a plan view of the current sensor in FIG. 4 from a direction shown with an arrow V. FIGS. 4 and 5 do not show a portion of a housing which will be described later.

As shown in FIGS. 1 to 5, the plurality of current sensors according to the first example embodiment of the present invention include a first current sensor 100a, a second current sensor 100b, and a third current sensor 100c.

The plurality of current sensors include a plurality of measurement target bus bars through which a current to be measured flows, the plurality of measurement target bus bars being arranged adjacently at a distance in a first direction (an X-axis direction). Specifically, a first bus bar 110a, a second bus bar 110b, and a third bus bar 110c through which the current to be measured flows are arranged adjacently at a distance in the first direction (X-axis direction). First bus bar 110a, second bus bar 110b, and third bus bar 110c are three-phase three-wire bus bars. For example, an alternating-current (AC) current of a U phase flows through first bus bar 110a, an AC current in a V phase flows through second bus bar 110b, and an AC current of a W phase flows through third bus bar 110c.

First current sensor 100a includes first bus bar 110a and a magnetic sensor 160 arranged at a distance from first bus bar 110a in a second direction (a Z-axis direction) orthogonal or substantially orthogonal to the first direction (X-axis direction). Second current sensor 100b includes second bus bar 110b and magnetic sensor 160 arranged at a distance from second bus bar 110b in the second direction (Z-axis direction). Third current sensor 100c includes third bus bar 110c and magnetic sensor 160 arranged at a distance from third bus bar 110c in the second direction (Z-axis direction).

Three magnetic sensors 160 are mounted on a substrate 170 at a distance from one another in the first direction (X-axis direction). Three magnetic sensors 160 do not necessarily have to be mounted on a single substrate 170. At least one magnetic sensor 160 of three magnetic sensors 160 may be arranged at a position different in the second direction (Z-axis direction) from another magnetic sensor 160 among three magnetic sensors 160. Magnetic sensor 160 includes a first magnetic detector 120a and a second magnetic detector 120b, a processing circuit 130, a housing 140, an input terminal 150, and a signal terminal 151.

First magnetic detector 120a and second magnetic detector 120b and processing circuit 130 are accommodated in housing 140. In the present example embodiment, housing 140 includes a base 141 including an accommodation space and a cover 142. Housing 140 is made of, for example, a thermoplastic resin such as engineering plastic or a thermosetting resin such as an epoxy resin or a urethane resin.

As shown in FIG. 4, each of input terminal 150 and signal terminal 151 is electrically connected to processing circuit 130 in the inside of housing 140. Each of input terminal 150 and signal terminal 151 extends from the inside to the outside of housing 140 and is electrically connected to an electrical circuit of substrate 170. Input terminal 150 extends to one side of a third direction (a Y-axis direction) orthogonal or substantially orthogonal to each of the first direction (X-axis direction) and the second direction (Z-axis direction) and signal terminal 151 extends to the other side of the third direction (Y-axis direction).

In the present example embodiment, each of input terminal 150 and signal terminal 151 is defined by, for example, a lead frame made of a conductive metal such as copper. When magnetic sensor 160 is provided by a pre-molded package, base 141 is molded as being integrated with the lead frame.

Each of input terminal 150 and signal terminal 151 may be provided from a single printed board. A core material of the printed board is made of, for example, glass epoxy or a thermosetting resin such as an epoxy resin, a phenol resin, a melamine resin, or a urethane resin.

Each of first magnetic detector 120a and second magnetic detector 120b is opposed to the measurement target bus bar at a distance in the second direction (Z-axis direction). The interval in the second direction (Z-axis direction) between second magnetic detector 120b and the measurement target bus bar is larger than the interval in the second direction (Z-axis direction) between first magnetic detector 120a and the measurement target bus bar.

As shown in FIGS. 3 to 5, second current sensor 100b will be described by way of illustration. Each of first magnetic detector 120a and second magnetic detector 120b is opposed to second bus bar 110b at a distance in the second direction (Z-axis direction). Specifically, each of first magnetic detector 120a and second magnetic detector 120b is fixed onto base 141 of housing 140 with, for example, a die attach film, an insulating adhesive, a conductive adhesive, or the like.

The interval in the second direction (Z-axis direction) between second magnetic detector 120b and second bus bar 110b is larger than the interval in the second direction (Z-axis direction) between first magnetic detector 120a and second bus bar 110b. Specifically, in base 141, a position of placement of second magnetic detector 120b is higher than a position of placement of first magnetic detector 120a.

In the present example embodiment, first magnetic detector 120a and second magnetic detector 120b are aligned with each other in the third direction (Y-axis direction). As shown in FIG. 5, first magnetic detector 120a and second magnetic detector 120b are superimposed on a central portion C in the first direction (X-axis direction) of second bus bar 110b when viewed from the second direction (Z-axis direction).

As shown in FIG. 4, processing circuit 130 is electrically connected to each of first magnetic detector 120a and second magnetic detector 120b. Processing circuit 130 is defined by, for example, an integrated circuit (IC) chip such as an application specific integrated circuit (ASIC). First magnetic detector 120a and second magnetic detector 120b and processing circuit 130 may be defined by a single IC chip. Processing circuit 130 is fixed onto base 141 of housing 140 with, for example, a die attach film, an insulating adhesive, a conductive adhesive, or the like.

Processing circuit 130 is electrically connected to input terminal 150 and supplied with a drive power supply. Processing circuit 130 processes a detection signal from each of first magnetic detector 120a and second magnetic detector 120b. Processing circuit 130 is electrically connected to signal terminal 151, and an output signal resulting from processing of the detection signal by processing circuit 130 is outputted from signal terminal 151.

As shown in FIG. 4, in the present example embodiment, each of first magnetic detector 120a and second magnetic detector 120b is electrically connected to processing circuit 130 by, for example, wire bonding. Each of input terminal 150 and signal terminal 151 is electrically connected to processing circuit 130 by, for example, wire bonding. Processing circuit 130 may be electrically connected to a lead frame or a printed board by flip-chip mounting, for example.

First magnetic detector 120a and second magnetic detector 120b and processing circuit 130 are coated with a coating material such as, for example, a silicone resin or an epoxy resin. In an example in which magnetic sensor 160 is provided by a transfer molded package, first magnetic detector 120a and second magnetic detector 120b and processing circuit 130 are sealed with a mold resin, for example.

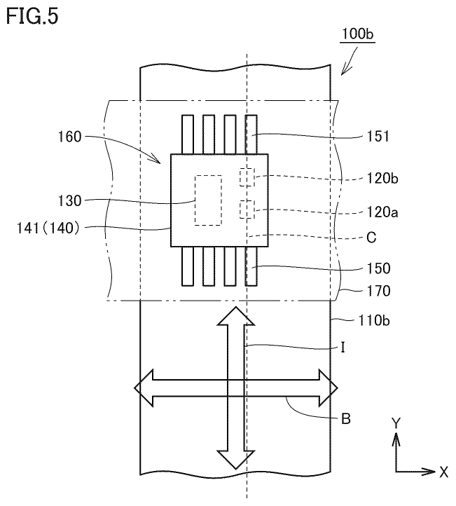

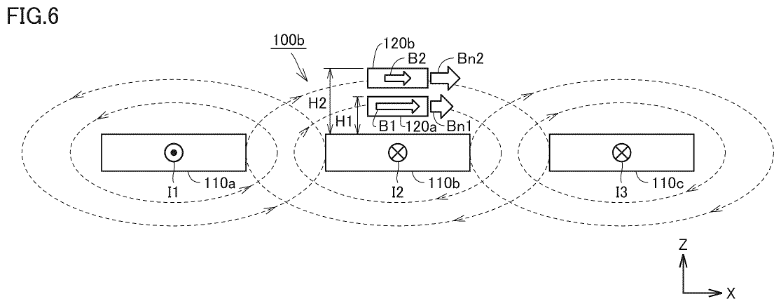

FIG. 6 is a schematic diagram showing a magnetic field applied to each of the first magnetic detector and the second magnetic detector when currents flow through the plurality of measurement target bus bars in the plurality of current sensors according to the first example embodiment of the present invention. FIG. 6 shows second current sensor 100b by way of illustration.

As shown in FIGS. 3 to 6, a current I that flows through each of first bus bar 110a, second bus bar 110b, and third bus bar 110c flows along the third direction (Y-axis direction). For example, as shown in FIG. 6, each of a current I2 that flows through second bus bar 110b and a current I3 that flows through third bus bar 110c flows toward one side of the third direction (Y-axis direction). A current I1 that flows through first bus bar 110a flows toward the other side of the third direction (Y-axis direction).

Consequently, a magnetic field is generated around each of first bus bar 110a, second bus bar 110b, and third bus bar 110c. As shown in FIGS. 5 and 6, each of first magnetic detector 120a and second magnetic detector 120b detects a magnetic field component in the first direction (X-axis direction) of the magnetic field.

As shown in FIG. 6, second current sensor 100b will be described by way of illustration. Current I2 to be measured flows through second bus bar 110b, current I1 flows through first bus bar 110a which is an adjacent bus bar, and current I3 flows through third bus bar 110c which is an adjacent bus bar.

An interval H2 in the second direction (Z-axis direction) between second magnetic detector 120b and second bus bar 110b is larger than an interval H1 in the second direction (Z-axis direction) between first magnetic detector 120a and second bus bar 110b. Therefore, in a magnetic field generated by current I2 that flows through second bus bar 110b, a magnetic field component B1 in the first direction (X-axis direction) applied to first magnetic detector 120a is larger than a magnetic field component B2 in the first direction (X-axis direction) applied to second magnetic detector 120b.

In an external magnetic field which is a combination of a magnetic field generated by current I1 that flows through first bus bar 110a and a magnetic field generated by current I3 that flows through third bus bar 110c, on the other hand, a magnetic field component Bn2 in the first direction (X-axis direction) applied to second magnetic detector 120b is larger than a magnetic field component Bn1 in the first direction (X-axis direction) applied to first magnetic detector 120a.

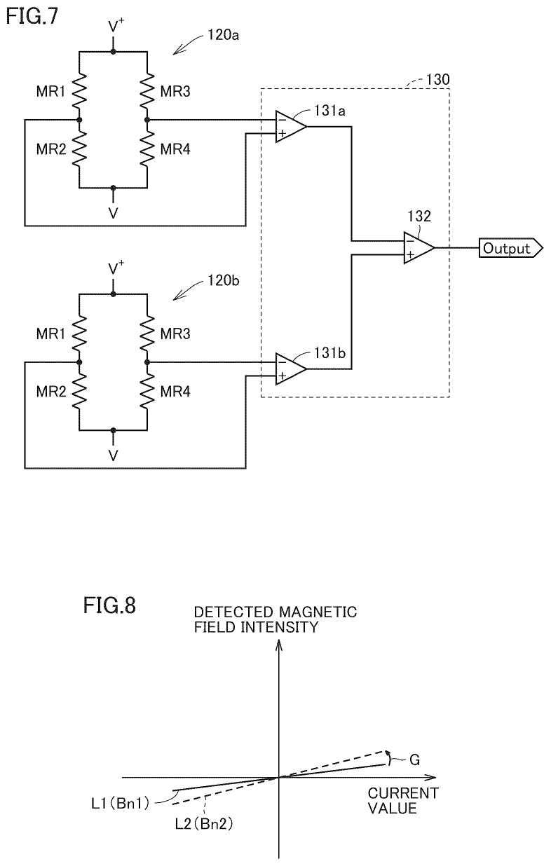

FIG. 7 is a circuit diagram showing a circuit configuration of the first magnetic detector and the second magnetic detector and the processing circuit in the plurality of current sensors according to the first example embodiment of the present invention. As shown in FIG. 7, each of first magnetic detector 120a and second magnetic detector 120b includes a Wheatstone bridge circuit including four tunnel magneto resistance (TMR) elements. Each of first magnetic detector 120a and second magnetic detector 120b may include a bridge circuit including, for example, a magneto resistance element such as a giant magneto resistance (GMR) element or an anisotropic magneto resistance (AMR) element, instead of the TMR element. Alternatively, each of first magnetic detector 120a and second magnetic detector 120b may include, for example, a half bridge circuit including two magneto resistance elements. Furthermore, each of first magnetic detector 120a and second magnetic detector 120b may be, for example, a Hall element. Each of first magnetic detector 120a and second magnetic detector 120b may include an IC therein.

In the present example embodiment, each of first magnetic detector 120a and second magnetic detector 120b includes a sensitivity axis oriented to one side of the first direction (X-axis direction), and includes such odd-function input and output characteristics as outputting a positive value when it detects a magnetic field component oriented to one side of the first direction (X-axis direction) and outputting a negative value when it detects a magnetic field component oriented to the other side of the first direction (X-axis direction).

Processing circuit 130 includes a first operational amplifier 131a, a second operational amplifier 131b, and a third operational amplifier 132. First operational amplifier 131a is, for example, a differential amplifier and electrically connected to each of first magnetic detector 120a and third operational amplifier 132. First operational amplifier 131a can adjust sensitivity of first magnetic detector 120a.

Second operational amplifier 131b is, for example, a differential amplifier and is electrically connected to each of second magnetic detector 120b and third operational amplifier 132. Second operational amplifier 131b can adjust sensitivity of second magnetic detector 120b.

In the present example embodiment, third operational amplifier 132 is, for example, a differential amplifier. When first magnetic detector 120a and second magnetic detector 120b are reverse to each other in direction of the sensitivity axis, however, third operational amplifier 132 is, for example, a summing amplifier. Third operational amplifier 132 can adjust sensitivity of second current sensor 100b.

Processing performed in processing circuit 130 will now be described.

FIG. 8 shows a graph of a relationship between a value of a current that flows through each of the first bus bar and the third bus bar and detected magnetic field intensity detected by each of the first magnetic detector and the second magnetic detector of the second current sensor when the current flows only through the first bus bar and the third bus bar. In FIG. 8, the ordinate represents detected magnetic field intensity detected by each of the first magnetic detector and the second magnetic detector and the abscissa represents a value of the current that flows through each of the first bus bar and the third bus bar. Detected magnetic field intensity detected by the first magnetic detector is shown with a solid line L1 and detected magnetic field intensity detected by the second magnetic detector is shown with a dotted line L2.

As set forth above, in an external magnetic field which is a combination of a magnetic field generated by current I1 that flows through first bus bar 110a and a magnetic field generated by current I3 that flows through third bus bar 110c, magnetic field component Bn2 in the first direction (X-axis direction) applied to second magnetic detector 120b is larger than magnetic field component Bn1 in the first direction (X-axis direction) applied to first magnetic detector 120a.

Therefore, as shown in FIG. 8, a detected magnetic field intensity of a magnetic field component Bn2 in the first direction (X-axis direction) of an external magnetic field applied to second magnetic detector 120b is higher than detected magnetic field intensity of a magnetic field component Bn1 in the first direction (X-axis direction) of an external magnetic field applied to first magnetic detector 120a.

Processing circuit 130 then corrects sensitivity of first magnetic detector 120a such that detection values obtained by first magnetic detector 120a and second magnetic detector 120b, of the magnetic field component in the first direction (X-axis direction) of an external magnetic field are equal or substantially equal to each other.

Specifically, processing circuit 130 increases sensitivity of first magnetic detector 120a such that detection values obtained by first magnetic detector 120a and second magnetic detector 120b, of the magnetic field component in the first direction (X-axis direction) of an external magnetic field are equal or substantially equal to each other, by increasing an amplification factor of first operational amplifier 131a as shown with an arrow G in FIG. 8. In other words, the processing circuit increases the sensitivity of first magnetic detector 120a by a factor of (Bn2/Bn1). The relationship of (Bn2/Bn1)>1 is satisfied. Since intensity of a generated magnetic field linearly increases with the value of the current that flows through the bus bar, Bn2/Bn1 is constant.

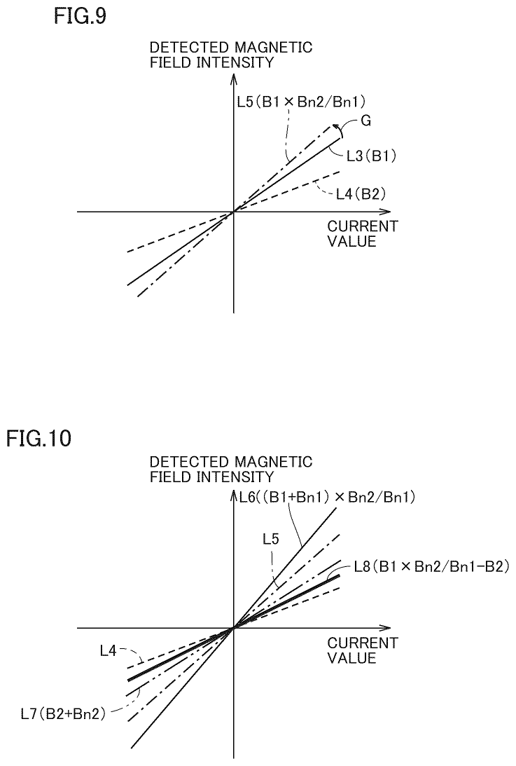

FIG. 9 shows a graph of a relationship between a value of a current that flows through the second bus bar and detected magnetic field intensity detected by each of the first magnetic detector and the second magnetic detector of the second current sensor when the current flows only through the second bus bar. In FIG. 9, the ordinate represents detected magnetic field intensity detected by each of the first magnetic detector and the second magnetic detector and the abscissa represents a value of a current that flows through the second bus bar. Detected magnetic field intensity detected by the first magnetic detector before correction is shown with a solid line L3, detected magnetic field intensity detected by the second magnetic detector is shown with a dotted line L4, and detected magnetic field intensity detected by the first magnetic detector after correction is shown with a chain dotted line L5.

As set forth above, in a magnetic field generated by current I2 to be measured that flows through second bus bar 110b, magnetic field component B1 in the first direction (X-axis direction) applied to first magnetic detector 120a is larger than magnetic field component B2 in the first direction (X-axis direction) applied to second magnetic detector 120b.

Therefore, as shown in FIG. 9, a detected magnetic field intensity of a magnetic field component B1 in the first direction (X-axis direction) of a magnetic field applied to first magnetic detector 120a before correction is higher than detected magnetic field intensity of a magnetic field component B2 in the first direction (X-axis direction) of a magnetic field applied to second magnetic detector 120b. In addition, detected magnetic field intensity of a magnetic field component B1 detected by first magnetic detector 120a corrected to increase the sensitivity as shown with arrow G is higher by the factor of (Bn2/Bn1) than detected magnetic field intensity of a magnetic field component B1 detected by first magnetic detector 120a before correction.

FIG. 10 shows a graph of a relationship between a value of a current that flows through each of the first bus bar to the third bus bar and detected magnetic field intensity detected by each of the first magnetic detector and the second magnetic detector of the second current sensor when the current flows through each of the first bus bar to the third bus bar. In FIG. 10, the ordinate represents detected magnetic field intensity detected by each of the first magnetic detector and the second magnetic detector and the abscissa represents a value of a current that flows through each of the first bus bar to the third bus bar. Detected magnetic field intensity detected by the first magnetic detector after correction is shown with a thin solid line L6, detected magnetic field intensity detected by the second magnetic detector is shown with a chain double dotted line L7, and a difference between detected magnetic field intensity detected by the first magnetic detector after correction and detected magnetic field intensity detected by the second magnetic detector is shown with a thick solid line L8.

As shown in FIG. 10, detected magnetic field intensity of a magnetic field component (B1+Bn1) in the first direction (X-axis direction) of a magnetic field applied to first magnetic detector 120a after correction is higher than detected magnetic field intensity of a magnetic field component (B2+Bn2) in the first direction (X-axis direction) of a magnetic field applied to second magnetic detector 120b.

Processing circuit 130 calculates a value of current I2 to be measured, by calculating a difference between detected magnetic field intensity detected by first magnetic detector 120a after correction and detected magnetic field intensity detected by second magnetic detector 120b. Specifically, third operational amplifier 132 calculates a difference between an output value from first operational amplifier 131a and an output value from second operational amplifier 131b.

The sensitivity of first magnetic detector 120a after correction was increased by the factor of (Bn2/Bn1) as set forth above. Therefore, detected magnetic field intensity of a magnetic field component (B1+Bn1) detected by first magnetic detector 120a after correction is calculated as ((B1+Bn1)×Bn2/Bn1). Therefore, the difference between detected magnetic field intensity detected by first magnetic detector 120a after correction and detected magnetic field intensity detected by second magnetic detector 120b is calculated as ((B1+Bn1)×Bn2/Bn1)−(B2+Bn2)=B1×Bn2/Bn1−B2.

Detected magnetic field intensity of a magnetic field component Bn1 detected by first magnetic detector 120a after correction thus becomes equal or substantially equal to detected magnetic field intensity of a magnetic field component Bn2 detected by second magnetic detector 120b, and they reduce and cancel each other, so that an external magnetic field can be canceled. First bus bar 110a and third bus bar 110c which are adjacent bus bars are arranged to satisfy the relationship of (Bn2/Bn1)>1, so that the differential output value from processing circuit 130 increases and an S/N ratio can be improved.

As set forth above, while processing circuit 130 performs mutual reduction and cancellation of detection values obtained by first magnetic detector 120a and second magnetic detector 120b, of the magnetic field component in the first direction (X-axis direction) of an external magnetic field generated from first bus bar 110a and third bus bar 110c which are adjacent bus bars, processing circuit 130 calculates a value of current I2 that flows through second bus bar 110b which is the measurement target bus bar, based on a difference in absolute value between the detection values obtained by first magnetic detector 120a and second magnetic detector 120b, of the magnetic field component in the first direction (X-axis direction) of a magnetic field generated by current I2 that flows through second bus bar 110b which is the measurement target bus bar.

A result of analysis of simulation in the plurality of current sensors according to the present example embodiment will now be described.

FIG. 11 shows a graph of a relationship between a value of a current that flows through each of the first bus bar to the third bus bar and an output value from each of the first magnetic detector and the second magnetic detector of the second current sensor when the current flows through each of the first bus bar to the third bus bar. In FIG. 11, the ordinate represents an output value (V) from each of the first magnetic detector and the second magnetic detector and the abscissa represents a value (A) of a current that flows through each of the first bus bar to the third bus bar. The output value from the first magnetic detector is shown with a solid line and the output value from the second magnetic detector is shown with a dotted line.

As shown in FIG. 11, the output value from first magnetic detector 120a before correction was larger than the output value from second magnetic detector 120b.

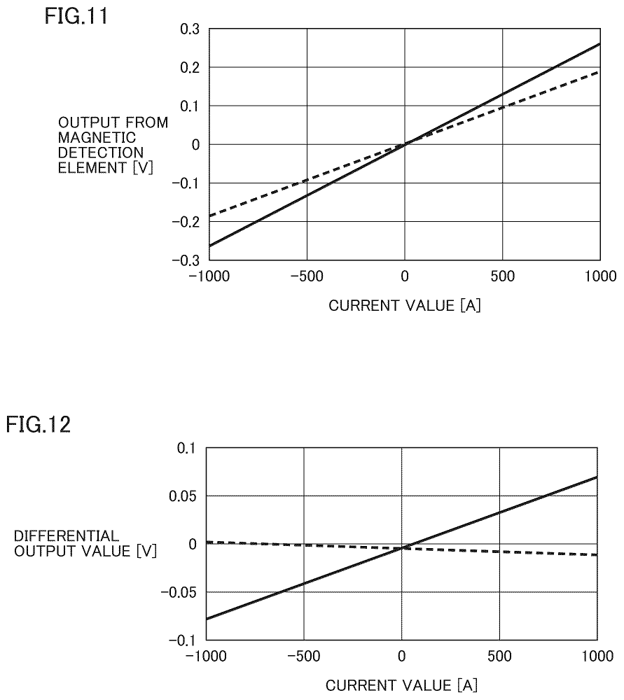

FIG. 12 shows a graph of a differential output value between an output value based on magnetic field component B1 from the first magnetic detector before correction and an output value based on magnetic field component B2 from the second magnetic detector and a differential output value between an output value based on magnetic field component Bn1 from the first magnetic detector before correction and an output value based on magnetic field component Bn2 from the second magnetic detector. In FIG. 12, the ordinate represents a differential output value (V) and the abscissa represents a value (A) of a current that flows through each of the first bus bar to the third bus bar. The differential output value between the output value based on magnetic field component B1 from the first magnetic detector before correction and the output value based on magnetic field component B2 from the second magnetic detector is shown with a solid line and the differential output value between the output value based on magnetic field component Bn1 from the first magnetic detector before correction and the output value based on magnetic field component Bn2 from the second magnetic detector is shown with a dotted line.

As shown in FIG. 12, the differential output value between the output value based on magnetic field component Bn1 from first magnetic detector 120a before correction and the output value based on magnetic field component Bn2 from second magnetic detector 120b is not constant and an influence by an external magnetic field could not be canceled.

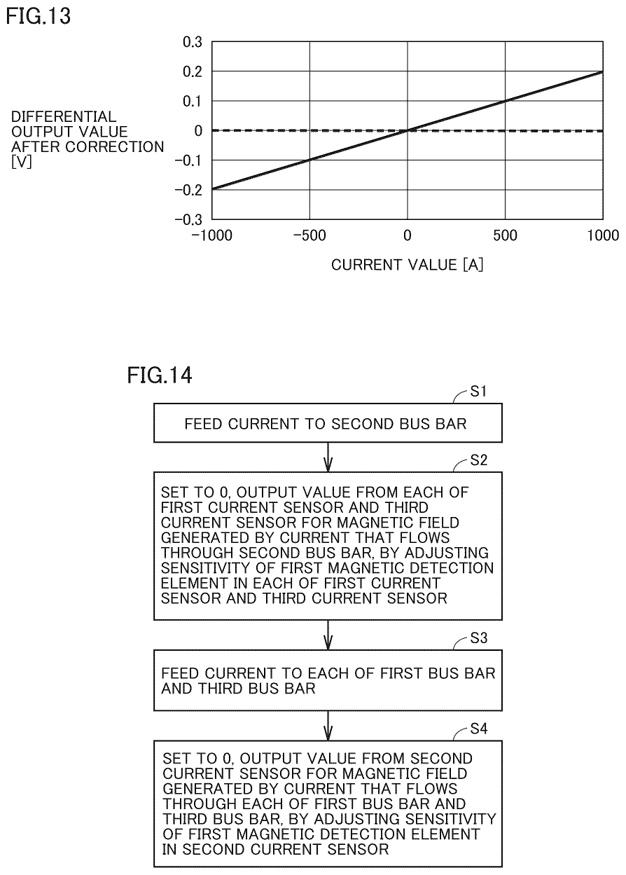

FIG. 13 shows a graph of a differential output value between an output value based on magnetic field component B1 from the first magnetic detector after correction and an output value based on magnetic field component B2 from the second magnetic detector and a differential output value between an output value based on magnetic field component Bn1 from the first magnetic detector after correction and an output value based on magnetic field component Bn2 from the second magnetic detector. In FIG. 13, the ordinate represents a differential output value (V) and the abscissa represents a value (A) of a current that flows through each of the first bus bar to the third bus bar. The differential output value between the output value based on magnetic field component B1 from the first magnetic detector after correction and the output value based on magnetic field component B2 from the second magnetic detector is shown with a solid line and the differential output value between the output value based on magnetic field component Bn1 from the first magnetic detector after correction and the output value based on magnetic field component Bn2 from the second magnetic detector is shown with a dotted line.

As shown in FIG. 13, the differential output value between the output value based on magnetic field component Bn1 from first magnetic detector 120a after correction and the output value based on magnetic field component Bn2 from second magnetic detector 120b is constant at 0 and an influence by an external magnetic field were canceled. As compared with a state before correction, the differential output value between the output value based on magnetic field component B1 from the first magnetic detector after correction and the output value based on magnetic field component B2 from the second magnetic detector increased and the S/N ratio were improved.

It could be confirmed based on the results of analysis of the simulation that the current sensor according to the present example embodiment was able to accurately measure the value of the current to be measured, by canceling an external magnetic field even when a non-uniform external magnetic field was applied to first magnetic detector 120a and second magnetic detector 120b.

In the current sensor according to the present example embodiment, first magnetic detector 120a and second magnetic detector 120b are aligned in the third direction (Y-axis direction). Each of first magnetic detector 120a and second magnetic detector 120b can thus readily be connected to processing circuit 130 through a wire.

In the current sensor according to the present example embodiment, first magnetic detector 120a and second magnetic detector 120b are superimposed on central portion C in the first direction (X-axis direction) of second bus bar 110b when viewed from the second direction (Z-axis direction). Influence by an external magnetic field can thus be reduced and a value of a current to be measured can more accurately be measured.

Although an example of a method of correction of second current sensor 100b is illustrated and described above, an example of a method of successive correction of first current sensor 100a, second current sensor 100b, and third current sensor 100c will be described.

FIG. 14 is a flowchart showing an example of a method of successive correction of the plurality of current sensors. As shown in FIG. 14, initially, a current is fed to second bus bar 110b (step S1). By adjustment of sensitivity of first magnetic detector 120a in each of first current sensor 100a and third current sensor 100c in that state, an output value from each of first current sensor 100a and third current sensor 100c for a magnetic field generated by the current that flows through second bus bar 110b is set to 0 (step S2).

A current is then fed to each of first bus bar 110a and third bus bar 110c (step S3). By adjustment of sensitivity of first magnetic detector 120a in second current sensor 100b in that state, the output value from second current sensor 100b for a magnetic field generated by the current that flows through each of first bus bar 110a and third bus bar 110c is set to 0 (step S4).

As set forth above, in the plurality of current sensors according to the present example embodiment, a first step (steps S1 and S2) is performed to set to 0, the detection value obtained by first current sensor 100a including first bus bar 110a which is another measurement target bus bar adjacent to second bus bar 110b which is one measurement target bus bar among the plurality of measurement target bus bars, of the magnetic field component in the first direction (X-axis direction) of a magnetic field generated by the current that flows through second bus bar 110b, by correcting sensitivity of first magnetic detector 120a in first current sensor 100a when the current is fed to second bus bar 110b.

Furthermore, in the first step, the detection value obtained by third current sensor 100c including third bus bar 110c which is yet another measurement target bus bar adjacent to second bus bar 110b which is one measurement target bus bar among the plurality of measurement target bus bars, of the magnetic field component in the first direction (X-axis direction) of a magnetic field generated by the current that flows through second bus bar 110b is set to 0, by correcting the sensitivity of first magnetic detector 120a also in third current sensor 100c when the current is fed to second bus bar 110b. In an example in which only two measurement target bus bars are provided, this correction of third current sensor 100c is not performed.

A second step (steps S3 and S4) is then performed to set to 0, the detection value obtained by second current sensor 100b including second bus bar 110b, of the magnetic field component in the first direction (X-axis direction) of a magnetic field generated by the current that flows through each of first bus bar 110a and third bus bar 110c, by correcting the sensitivity of first magnetic detector 120a in second current sensor 100b when the current is fed to each of first bus bar 110a and third bus bar 110c.

Since there is no third bus bar 100c in the example where only two measurement target bus bars are provided, the current is fed to first bus bar 110a in the second step.

A step of adjusting each of first current sensor 100a to third current sensor 100c to a desired sensitivity by adjusting the amplification factor of third operational amplifier 132 in each current sensor including the bus bar through which a current flows by successive feed of the current to each of first bus bar 110a to third bus bar 110c may further be included.

For example, a method of blowing a fuse connected to first operational amplifier 131a in processing circuit 130 to change a resistance value of a circuit or a method of changing the amplification factor of first operational amplifier 131a with the use of an amplification circuit in processing circuit 130 may be applicable as the method of correcting sensitivity of first magnetic detector 120a.

With the correction method, while mutual influence by a plurality of adjacently arranged measurement target bus bars is reduced or prevented, each of the plurality of current sensors can accurately measure a value of a current to be measured that flows through each of the plurality of measurement target bus bars.

### Second Example Embodiment

A current sensor according to a second example embodiment of the present invention will be described below with reference to the drawings. The current sensor according to the second example embodiment of the present invention is different from the current sensor according to the first example embodiment of the present invention in the arrangement of the first magnetic detector and the second magnetic detector, and description of features the same as or similar to those in the current sensor according to the first example embodiment of the present invention will not be repeated.

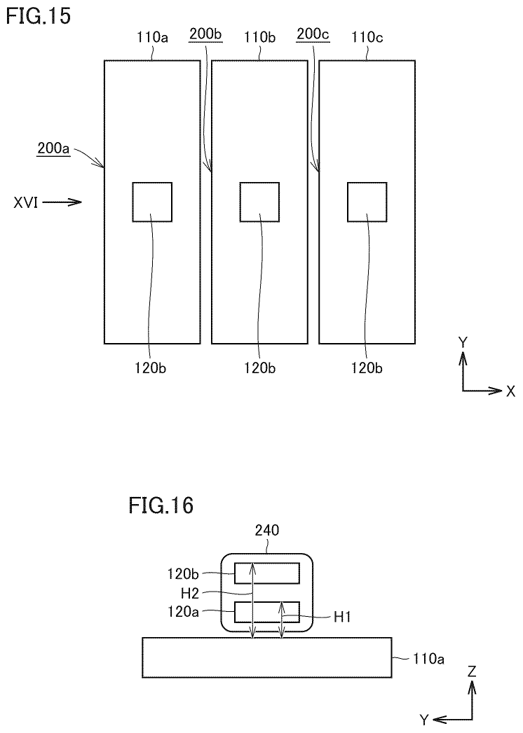

FIG. 15 is a plan view showing a relationship of the arrangement of the measurement target bus bar, the first magnetic detector, and the second magnetic detector in a current sensor according to the second example embodiment of the present invention. FIG. 16 is a side view of the relationship of the arrangement in FIG. 15 from a direction shown with an arrow XVI. FIG. 15 does not show a housing 240.

As shown in FIGS. 15 and 16, in each of a first current sensor 200a, a second current sensor 200b, and a third current sensor 200c according to the second example embodiment of the present invention, first magnetic detector 120a and second magnetic detector 120b are superimposed on each other when viewed from the second direction (Z-axis direction). In the present example embodiment, first magnetic detector 120a is located between the measurement target bus bar and second magnetic detector 120b. First magnetic detector 120a and second magnetic detector 120b are accommodated in housing 240.

Interval H2 in the second direction (Z-axis direction) between second magnetic detector 120b and the measurement target bus bar is larger than interval H1 in the second direction (Z-axis direction) between first magnetic detector 120a and the measurement target bus bar.

In the current sensor according to the second example embodiment of the present invention, first magnetic detector 120a and second magnetic detector 120b are superimposed on each other when viewed from the second direction (Z-axis direction), so that housing 240 can be reduced in size.

Although positions in the first direction (X-axis direction), of first magnetic detector 120a and second magnetic detector 120b coincide with each other in the present example embodiment, positions in the first direction (X-axis direction), of first magnetic detector 120a and second magnetic detector 120bmay be displaced from each other as long as first magnetic detector 120a and second magnetic detector 120b are superimposed on each other at least in a portion in the second direction (Z-axis direction).

Although first magnetic detector 120a and second magnetic detector 120b are arranged such that magnetism sensing surfaces of first magnetic detector 120a and second magnetic detector 120b extend along an XY plane in the present example embodiment, first magnetic detector 120a and second magnetic detector 120b may be arranged such that the magnetism sensing surfaces of first magnetic detector 120a and second magnetic detector 120b extend along an XZ plane. A modification in which first magnetic detector 120a and second magnetic detector 120b are arranged such that the magnetism sensing surfaces of first magnetic detector 120a and second magnetic detector 120b extend along the XZ plane will be described with reference to the drawings.

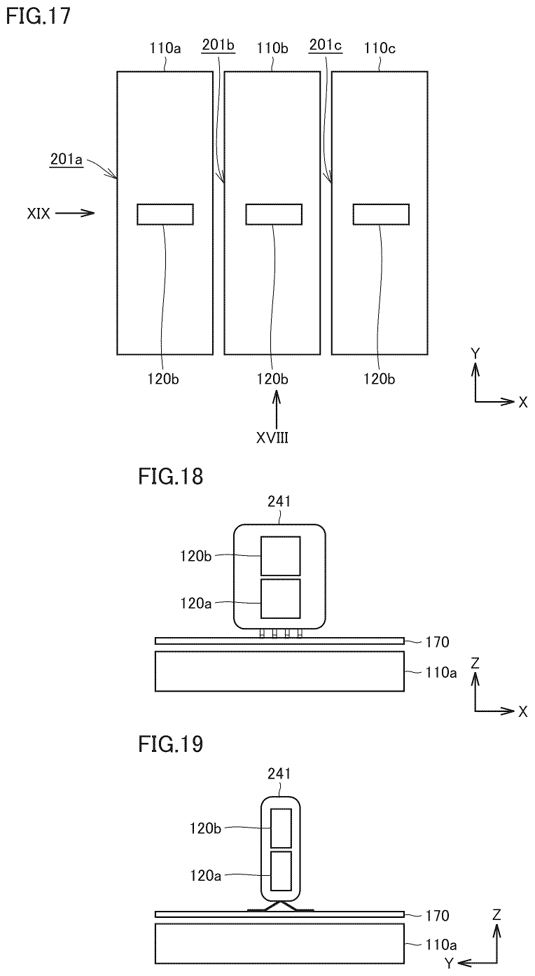

FIG. 17 is a plan view showing a relationship of the arrangement of the measurement target bus bar, the first magnetic detector, and the second magnetic detector in a current sensor according to the modification of the second example embodiment of the present invention. FIG. 18 is a front view showing the relationship of the arrangement in FIG. 17 from a direction shown with an arrow XVIII. FIG. 19 is a side view showing the relationship of the arrangement in FIG. 17 from a direction shown with an arrow XIX. FIG. 17 does not show substrate 170 and a housing 241.

As shown in FIGS. 17 to 19, in each of a first current sensor 201a, a second current sensor 201b, and a third current sensor 201c according to the modification of the second example embodiment of the present invention, first magnetic detector 120a and second magnetic detector 120b are arranged such that the magnetism sensing surfaces thereof extend along the XZ plane and first magnetic detector 120a and second magnetic detector 120b are superimposed on each other when viewed from the second direction (Z-axis direction). First magnetic detector 120a and second magnetic detector 120b are accommodated in housing 241.

An interval in the second direction (Z-axis direction) between second magnetic detector 120b and the measurement target bus bar is larger than an interval in the second direction (Z-axis direction) between first magnetic detector 120a and the measurement target bus bar.

In the modification of the second example embodiment of the present invention, first magnetic detector 120a and second magnetic detector 120b are juxtaposed on a lead frame and sealed with resin, and thereafter bonded onto substrate 170 by bending a terminal portion of the lead frame. Then, as shown in FIGS. 17 to 19, first magnetic detector 120a and second magnetic detector 120b are arranged such that the magnetism sensing surfaces of first magnetic detector 120a and second magnetic detector 120b extend along the XZ plane. In the present modification, necessity for complicated processing such as provision of a height difference in the lead frame for making positions in the second direction (Z-axis direction) of first magnetic detector 120a and second magnetic detector 120b different can be avoided.

### Third Example Embodiment

A current sensor according to a third example embodiment of the present invention will be described below with reference to the drawings. The current sensor according to the third example embodiment of the present invention is different from the current sensor according to the second example embodiment of the present invention in the arrangement of the second magnetic detector, and description of features the same as or similar to those in the current sensor according to the second example embodiment of the present invention will not be repeated.

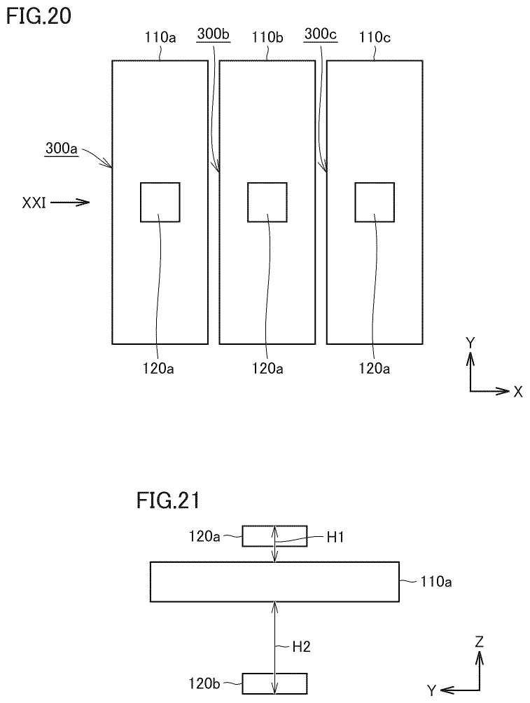

FIG. 20 is a plan view showing a relationship of an arrangement of the measurement target bus bar, the first magnetic detector, and the second magnetic detector in the current sensor according to the third example embodiment of the present invention. FIG. 21 is a side view of the relationship of the arrangement in FIG. 20 from a direction shown with an arrow XXI.

As shown in FIGS. 20 and 21, in each of a first current sensor 300a, a second current sensor 300b, and a third current sensor 300c according to the third example embodiment of the present invention, first magnetic detector 120a and second magnetic detector 120b are superimposed on each other when viewed from the second direction (Z-axis direction). In the present example embodiment, the measurement target bus bar is located between first magnetic detector 120a and second magnetic detector 120b.

Interval H2 in the second direction (Z-axis direction) between second magnetic detector 120b and the measurement target bus bar is larger than interval H1 in the second direction (Z-axis direction) between first magnetic detector 120a and the measurement target bus bar.

In the current sensor according to the third example embodiment of the present invention, first magnetic detector 120a and second magnetic detector 120b are located on opposing sides of the measurement target bus bar in the second direction (Z-axis direction) as being superimposed on each other when viewed from the second direction (Z-axis direction), so that a degree of freedom in the arrangement of first magnetic detector 120a and second magnetic detector 120b can be increased.

Although positions in the first direction (X-axis direction), of first magnetic detector 120a and second magnetic detector 120b coincide with each other in the present example embodiment, positions in the first direction (X-axis direction), of first magnetic detector 120a and second magnetic detector 120b may be displaced from each other as long as first magnetic detector 120a and second magnetic detector 120b are superimposed on each other at least in a portion in the second direction (Z-axis direction).

Features that can be combined in the description of the example embodiments described above may be combined with one another.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A current sensor comprising:
a measurement target bus bar through which a current to be measured flows;
an adjacent bus bar located adjacent to the measurement target bus bar at a distance in a first direction;
a first magnetic detector and a second magnetic detector to detect a magnetic field component in the first direction of a magnetic field generated by the current that flows through the measurement target bus bar while the first magnetic detector and the second magnetic detector are opposed to the measurement target bus bar at a distance in a second direction orthogonal or substantially orthogonal to the first direction;
a processing circuit electrically connected to each of the first magnetic detector and the second magnetic detector, the processing circuit being configured or programmed to process a detection signal from each of the first magnetic detector and the second magnetic detector; and
a signal terminal electrically connected to the processing circuit to output an output signal resulting from processing of the detection signal by the processing circuit; wherein
an interval in the second direction between the second magnetic detector and the measurement target bus bar is larger than an interval in the second direction between the first magnetic detector and the measurement target bus bar; and
the processing circuit is configured or programmed such that, while the processing circuit performs mutual reduction and cancellation of detection values obtained by the first magnetic detector and the second magnetic detector, of a magnetic field component in the first direction of an external magnetic field generated from the adjacent bus bar, the processing circuit calculates a value of the current that flows through the measurement target bus bar based on a difference in absolute value between the detection values obtained by the first magnetic detector and the second magnetic detector, of the magnetic field component in the first direction of the magnetic field generated by the current that flows in the measurement target bus bar.

2. The current sensor according to claim 1, wherein the processing circuit is configured or programmed to correct sensitivity of the first magnetic detector such that the detection values obtained by the first magnetic detector and the second magnetic detector, of the magnetic field component in the first direction of the external magnetic field generated from the adjacent bus bar are equal or substantially equal to each other.

3. The current sensor according to claim 2, wherein the processing circuit is configured or programmed to increase the sensitivity of the first magnetic detector such that the detection values obtained by the first magnetic detector and the second magnetic detector, of the magnetic field component in the first direction of the external magnetic field generated from the adjacent bus bar are equal to each other.

4. The current sensor according to claim 1, wherein the first magnetic detector and the second magnetic detector are aligned in a third direction orthogonal or substantially orthogonal to each of the first direction and the second direction.

5. The current sensor according to claim 1, wherein the first magnetic detector and the second magnetic detector are superimposed on each other when viewed from the second direction.

6. The current sensor according to claim 1, wherein each of the first magnetic detector and the second magnetic detector is superimposed on a central portion in the first direction of the measurement target bus bar when viewed from the second direction.

7. The current sensor according to claim 1, wherein the first magnetic detector, the second magnetic detector and the processing circuit are inside of a housing.

8. The current sensor according to claim 7, wherein the housing is made of thermoplastic resin or thermosetting resin.

9. The current sensor according to claim 1, wherein the signal terminal is defined by a lead frame.

10. The current sensor according to claim 1, wherein the processing circuit includes an includes an integrated circuit chip.

11. The current sensor according to claim 1, wherein each of the first and second magnetic detectors is electrically connected to the processing circuit by wiring bonding.

12. The current sensor according to claim 1, wherein the first and second magnetic detectors and the processing circuit are coated with silicone resin or epoxy resin.

13. The current sensor according to claim 1, wherein each of the first and second magnetic detectors includes a Wheatstone bridge circuit including four tunnel magneto resistance elements.

14. The current sensor according to claim 1, wherein each of the first and second magnetic detectors includes a Hall element.

15. A method of correcting a current sensor including a measurement target bus bar through which a current to be measured flows, an adjacent bus bar located adjacent to the measurement target bus bar at a distance in a first direction, and a first magnetic detector and a second magnetic detector to detect a magnetic field component in the first direction of a magnetic field generated by the current that flows through the measurement target bus bar while the first magnetic detector and the second magnetic detector are opposed to the measurement target bus bar at a distance in a second direction orthogonal to the first direction, the method comprising:
arranging the first and second magnetic detectors such that an interval in the second direction between the second magnetic detector and the measurement target bus bar is larger than an interval in the second direction between the first magnetic detector and the measurement target bus bar;
calculating a value of the current that flows through the measurement target bus bar based on a difference in absolute value between the detection values obtained by the first magnetic detector and the second magnetic detector; and
correcting a sensitivity of the first magnetic detector such that the detection values obtained by the first magnetic detector and the second magnetic detector of a magnetic field component in the first direction of an external magnetic field generated from the adjacent bus bar are equal or substantially equal to each other.

16. The method of correcting a current sensor according to claim 15, wherein the sensitivity of the first magnetic detector is increased such that the detection values obtained by the first magnetic detector and the second magnetic detector of the magnetic field component in the first direction of the external magnetic field generated from the adjacent bus bar are equal or substantially equal to each other.

17. A method of correcting a plurality of current sensors that measure a value of a current to be measured that flows through each of a plurality of measurement target bus bars through which the current flows, the plurality of measurement target bus bars being adjacent and spaced at a distance in a first direction, each of the plurality of current sensors include any one measurement target bus bar among the plurality of measurement target bus bars and including a first magnetic detector and a second magnetic detector to detect a magnetic field component in the first direction of a magnetic field generated by a current that flows through the measurement target bus bar while the first magnetic detector and the second magnetic detector are opposed to the measurement target bus bar at a distance in a second direction orthogonal or substantially orthogonal to the first direction, in each of the plurality of current sensors, an interval in the second direction between the second magnetic detector and an opposing measurement target bus bar is larger than an interval in the second direction between the first magnetic detector and the opposing measurement target bus bar, and in each of the plurality of current sensors, a value of the current that flows through the measurement target bus bar in each of the plurality of current sensors is calculated based on a difference in absolute value between detection values obtained by the first magnetic detector and the second magnetic detector, the method comprising:
a first step of setting to 0 a detection value obtained by the current sensor of a magnetic field component in the first direction of a magnetic field generated by the current that flows through the one measurement target bus bar by correcting a sensitivity of the first magnetic detector in a current sensor including another measurement target bus bar adjacent to the one measurement target bus bar when the current is fed to one measurement target bus bar among the plurality of measurement target bus bars; and
a second step of setting to 0, the detection value obtained by the current sensor including the one measurement target bus bar of a magnetic field component in the first direction of a magnetic field generated by the current that flows through the another measurement target bus bar by correcting the sensitivity of the first magnetic detector in the current sensor when the current is fed to the another measurement target bus bar.

18. The method of correcting a plurality of current sensors according to claim 17, wherein
in the first step, the detection value obtained by a current sensor including yet another measurement target bus bar adjacent to the one measurement target bus bar of the magnetic field component in the first direction of the magnetic field generated by the current that flows through the one measurement target bus bar is set to 0 by correcting sensitivity of the first magnetic detector also in the current sensor when the current is fed to the one measurement target bus bar among the plurality of measurement target bus bars; and
in the second step, the detection value obtained by the current sensor including the one measurement target bus bar of a magnetic field component in a first direction of a magnetic field generated by a current that flows through the yet another measurement target bus bar is set to 0 by correcting the sensitivity of the first magnetic detector in the current sensor when the current is fed to each of the another measurement target bus bar and the yet another measurement target bus bar.
